(19) United States
(12) Patent Application Publication
(10) Pub. No.: US 2008/0032064 A1
(43) Pub. Date: Feb. 7, 2008

(54) Selective sealing of porous dielectric materials

(75) Inventors: Roy G. Gordon, Cambridge, MA (US); Daewon Hong, Arlington, MA (US)

Correspondence Address: WILMERHALE/BOSTON, 60 STATE STREET, BOSTON, MA, 02109, US

(73) Assignee: President and Fellows of Harvard College

(21) Appl. No.: 11/827,131

(22) Filed: Jul. 10, 2007

Related U.S. Application Data
(60) Provisional application No. 60/819,712, filed on Jul. 10, 2006.

(51) Int. Cl. C23C 16/00

(52) U.S. Cl. 427/578; 427/255.4

(57) ABSTRACT

This invention relates to materials and processes for selective deposition of silica films on non-metallic areas of substrates while avoiding any significant deposition on metallic conductive areas. Silica sealed the surface pores of a porous dielectric by the reaction of an aluminum-containing compound with an alkoxysilanol. Metal layers are protected from this deposition of silica by adsorption of a partially fluorinated alkanethiol. This invention provides processes for producing semi-porous dielectric materials wherein surface porosity is significantly reduced or removed while internal porosity is preserved to maintain a desired low-k value for the overall dielectric material. At the same time, a clean metal surface is produced, so that low electrical resistances of connections between copper layers are maintained. The combination of low-k dielectric constant and low resistance allows construction of microelectronic devices operating at high speeds.

### CROSS-REFERENCE TO RELATED APPLICATION

This application claims the benefit under 35 U.S.C. §119(e) of U.S. Provisional Patent Application No. 60/819,712, filed on Jul. 10, 2006, entitled Selective Sealing of Porous Dielectric Materials, which is incorporated herein by reference in its entirety.

### BACKGROUND OF THE INVENTION

1. Field of the Invention

This invention relates to materials and processes for thin film deposition, and in particular, selective silica deposition on porous dielectric materials.

2. Description of the Related Art

Silica has remained the dielectric material of choice in microelectronics for much of the past four decades. However, as the sizes of microelectronic devices have become progressively smaller, and integrated circuits are reduced in size to deeper sub-micron dimensions, signal propagation delay, electrical cross talk between conductors, and power consumption are greatly increased due to parasitic capacitance and resistance. As transistors shrink and the total amount of interconnect wiring increases, delays in that wiring greatly impact circuit performance. As wires become closer together and operating frequencies climb, cross talk between adjacent lines can degrade signal integrity. A better insulator, i.e., one with a lower k value, between the wires or active device regions reduces this noise. Therefore, there has been a strong demand for low-k inter-metal dielectric materials instead of conventional silica. Further decreases in k values (to below a value of about 2.6) are believed necessary to meet the device performance and power dissipation requirements of microelectronic devices of the future.

Such low dielectric constants can be achieved by introducing porosity. Porous low-k materials can be made by spin coating, chemical vapor deposition (CVD) or polymerization. Examples of porous low-k materials include hydrogen silsesquioxane, methyl silsesquioxane, aerogels, xerogels, SiCxOHy, SiLK® (Dow Chemical), CORAL® (Novellus), Black Diamond® (Applied Materials), and CVD-deposited methyl silanes, etc. These materials have a density on the order of 1.2 grams/cc or less. The pore diameters typically lie in the range from about 1 to about 10 nm. The pores reduce the density and dielectric constant of the material.

Generally, these porous dielectrics contain an interconnected network of pores, some of which extend from the outer surface of the dielectric to inside the bulk material. These interconnections between the pores open up fast diffusion pathways through the ultra-low-k material. Metal atoms from the interconnections may diffuse into the porous insulating material layer. Such diffusion of metal atoms can lead to excessive leakage currents between other conductive interconnections and lead to a breakdown of the insulating characteristics of the insulating layer. Diffusion barriers are normally used to prevent such undesired diffusion. However, using conformal deposition techniques such as atomic layer deposition (ALD) or CVD to deposit-electrically conductive diffusion barriers onto porous material results in deposition of conducting material inside the pores and can even produce electrical short circuits through the low-k insulator. See, for example, W. Besling, et al. in Atomic Layer Deposition of Barriers for Interconnect, International Interconnect Technology Conference 2002.

Another problem that may result from the use of porous dielectric materials is that openings etched in such materials have relatively rough sidewalls due to the porous nature of the insulating material. This may prevent complete filling of the openings with the conductive metal. Undesirable voids, gaps and seams may be created, which increase the resistance and may later cause failures by nucleating voids induced by electro-migration.

Thus, what are needed are materials and methods for preserving the desired low-k attributes of porous insulating materials while reducing the aforementioned problems associated with porous structures. One solution has been proposed in patent application WO2003083167, in which a monolayer of a catalyst such as aluminum is deposited on the outer pores. Then the heated structure is exposed to vapors of a silanol in order to deposit a silica layer that effectively closes the surface pores. A disadvantage of this process is that it also deposits silica on any exposed copper surfaces. These copper surfaces are normally present at the top of previously-deposited copper wiring. These copper surfaces should be kept free of insulating material, such as silica, so that they can connect electrically to copper that is subsequently deposited to fill the via holes. Thus it would be desirable to have a process that selectively seals the pores of porous dielectrics without placing a significant amount of insulating material on exposed copper surfaces. U.S. Pat. No. 6,852,635 suggests that it might be possible to deposit a diffusive barrier layer selectively on an insulating surface without at the same time depositing any such barrier material on adjacent areas of a metal. As noted above, such diffusion barrier layers are typically conductive and deposition of conductive material inside the porous insulating layer can short circuit the low k insulating layer. Methods for depositing insulating materials is not disclosed.

### SUMMARY OF THE INVENTION

In one aspect of the present invention, thin silica layers are selectively deposited on the insulating surfaces, while retarding or avoiding silica deposition on metal surfaces exposed to the same conditions. The process is applied to substrates that have both electrically conducting (e.g., metal) and electrically insulating (e.g., dielectric) exposed regions on their surfaces. The result of the process is to deposit silica layers a few nm thick on the insulating areas, while depositing little (<1 nm) or no silica on the electrically conducting areas.

According to another aspect of the invention, a vapor deposition process seals the pores of a porous material without placing a significant amount of material on exposed metal surfaces.

In another aspect, the invention provides a process for depositing a thin film of silica that closes the surface pores of a porous low-k dielectric, while at the same time depositing little or no silica on adjacent metal surfaces, e.g., copper.

In one embodiment, the substrates are partially completed microelectronic circuits covered with porous insulating material having trenches and holes that expose areas of copper wiring. After processing according to the invention, the pores of the porous insulator are sealed by a layer of silica. At the same time, the copper areas remain relatively clean and open to form low-resistance connections to additional copper wiring subsequently deposited inside the trenches and holes in the insulator. The silica-sealed surface of the porous insulator facilitates the formation of continuous barriers against undesired diffusion of copper out of its wiring and into the insulator.

In one or more embodiments, a diffusion barrier layer is deposited on the sealed porous insulator to further reduce migration of metal ions into the surrounding areas.

In one aspect of the invention, a method of selectively forming a silica layer on a substrate includes exposing a substrate comprising metallic and insulating surfaces to a protecting agent that interacts selectively with the metallic surface to deposit a protective layer on at least a portion of the metallic surface; exposing the protected substrate to a catalytic agent that interacts selectively with the insulating surfaces to form a catalytic surface on at least a portion of the insulating surface; and exposing the substrate to a silanol vapor to form a silica layer only on the catalytic surface of the substrates.

In preferred embodiments of the present invention, the steps are carried out by exposures of the substrate to vapors of the reagents. Alternatively, the exposures can be done using liquid solutions of the reagents.

Typically, the pores of a porous insulating surface have a diameter of less than about 5-10 nm; however, pores up to about 30 nm in diameter can be sealed in a single deposition cycle according to one or more embodiments of the present invention.

The practice of the invention facilitates the production of electronic devices by sealing porous low-k insulators in them while maintaining low-resistance contact along the metal interconnections.

### BRIEF DESCRIPTION OF THE DRAWINGS

The foregoing and various other aspects, features, and advantages of the present invention, as well as the invention itself, may be more fully appreciated with reference to the following detailed description of the invention when considered in connection with the following drawings. The drawings are presented for the purpose of illustration only and are not intended to be limiting of the invention, in which:

FIG. 1 is a cross-sectional illustration a porous insulator with a hole or trench, wherein a silica layer is deposited on the walls of the hole or trench without at the same time depositing on copper surfaces adjacent to the hole or trench;

FIG. 2 is a process flow diagram illustrating the various steps of a vapor deposition process according to one or more embodiments of the present invention;

FIG. 3 is a cross-sectional illustration of an apparatus used in the practice of at least one embodiment of the invention;

FIGS. 4A-4C are schematic cross-sectional illustrations of (A) a dielectric material having a pore to which (B) a thin catalytic layer has been deposited on portions of the outer surface of the dielectric material and sidewalls of the pore, and to which (C) a material having a relatively low dielectric constant is subsequently deposited such that it reacts with the thin catalytic layer to form a seal over the opening of the pore and the adjacent outer surface of the dielectric material; and

FIGS. 5A-5G illustrate representative chemical reactions that are proposed to operate during at least one embodiment of the invention.

### DETAILED DESCRIPTION OF THE INVENTION

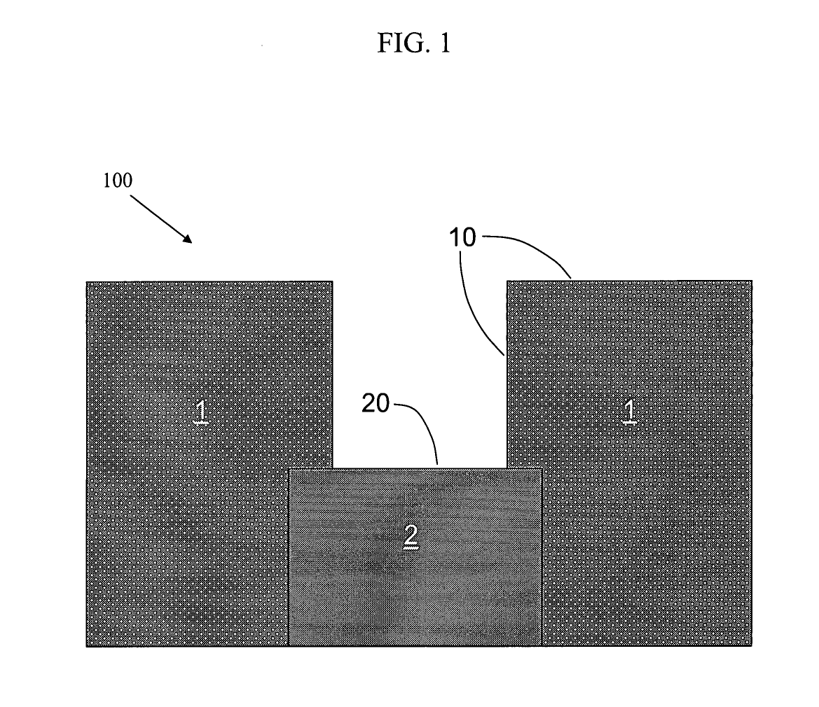

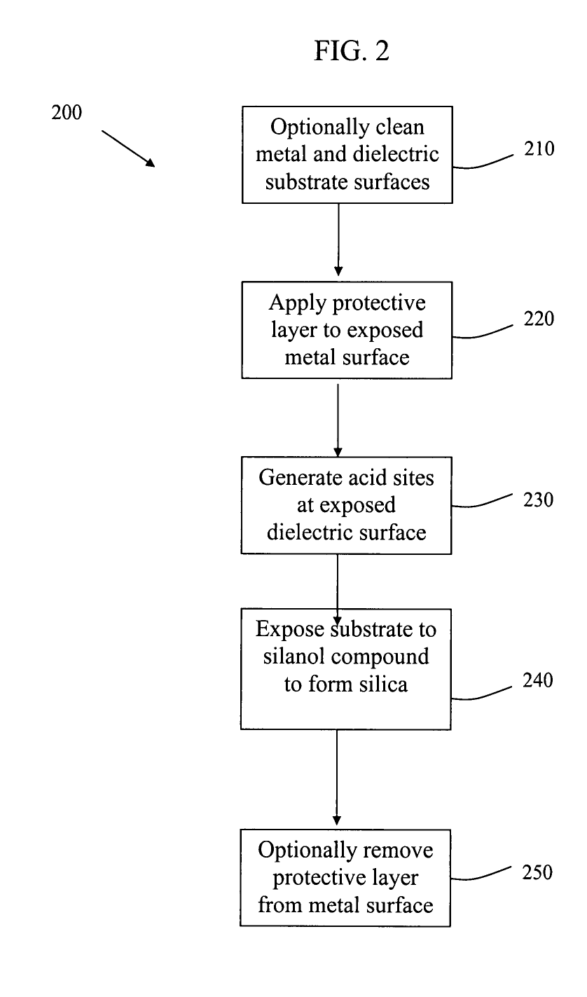

The process according to one or more embodiments of the present invention is described with reference to the schematic microelectronic device 100 shown in FIG. 1 and the process flow diagram 200 in FIG. 2. The exemplary microelectronic device 100 includes insulating element(s) 1 having top and side exposed surfaces 10 and metal element 2 having exposed surface 20. The insulating element may be porous and may include an interconnected network of pores (not shown) that can extend from the top and side outer surfaces of the porous insulating material into the interior of the material. Exemplary dielectric materials include silica, and porous low-k materials such as hydrogen silsesquioxane, methyl silsesquioxane, aerogels, xerogels, SiCxOHy, SiLK® (Dow Chemical), CORALS (Novellus), Black Diamond® (Applied Materials), and CVD-deposited methyl silanes, and the like. These materials have a density on the order of 1.2 grams/cc or less. The pore diameters typically lie in the range from about 1 to about 10 nm. Exemplary metals are those that are typically used to prepare conductive elements on modern microelectronic devices and can include copper, cobalt and ruthenium.

According to one or more embodiments of the present invention, the pore-sealing process comprises processing steps and optional steps for treating a substrate surface in order to selectively deposit thin silica layers on insulating surfaces, while retarding or avoiding silica deposition on metal surfaces exposed to the same conditions.

In an optional first step 210, surface 20 of the metal 2 and the surface 10 of the porous dielectric 1 are cleaned. For example, organic contamination is removed by oxidative agents such as ozone or oxygen atoms, followed by removal of metal oxide by reduction with a reducing agent such as formic acid or trioxane or by selective etching by a fluorinated beta-diketonate such as 1,1,1,5,5,5-hexafluoro-2,4-pentanedione optionally along with a complexing agent such as tert-butylisonitrile. The optional cleaning step is selected to clean the insulating layer, the conducting layer, or both.

In processing step 220, the device substrate 100 is exposed to a material that protects the metal surface 20 from further reaction. This protective material can include alkylthiols, dialkyldisulfides, alkylisonitriles, diazoalkanes and their fluorinated or partially fluorinated analogs that do not react with the surface of the porous dielectric.

In processing step 230, the device substrate 100 is then exposed to a metal or metalloid compound that generates catalytically reactive sites on the outer surface 10 and any exposed outer pores of the porous dielectric 1. The exposure time and/or reactivity of the metal or metalloid compound is selected so that the pores deeper inside the dielectric are not exposed to it and/or do not react with it during the time exposed. Suitable metal or metalloid compounds include metal or metalloid amides, amidinates, alkyls, alkoxides and halides. The metal or metalloid can be aluminum, boron, magnesium, scandium, lanthanum, yttrium, titanium, zirconium or hafnium.

Next in processing step 240, the device substrate 100 is then exposed to one or more silanol compounds, preferably at a temperature above room temperature. As used herein “silanol” refers to the class of compounds having a silicon atom bonded to one or more hydroxyl (OH) groups; silanols comprise alkoxysilanols, alkoxyalkylsilanols and alkoxysilanediols and their substituted derivatives. The acid sites on the surface catalyze the polymerization of the silanol into a layer of silica, which is deposited onto the exposed surfaces of the insulating material. When the exposed insulating material includes surfaces within and surrounding pores, the silica bridges over and seals the outer pores. The silanol reacts only slowly or not at all with the protected surface 20 of the metal.

An optional final step 250 removes the protective material and any traces of silica from the metal surfaces 20. The traces of silica may be removed by bombardment with reactive fluorine-containing ions directed at the surface, or by a fluorine-containing plasma or reactive vapor. The capping layer may be removed by a hydrogen-containing plasma, an oxygen-containing plasma, or by heating in the presence of oxygen or an oxidizing agent.

The individual process steps are described in detail below.

1. Cleaning of the Surfaces—Process Step 210.

An opening is created in an insulating layer to expose an underlying metal element. The opening can be created in the insulating layer using any conventional technique, e.g., by using a hard mask layer on top of the insulation layer. In exemplary microelectronic devices, the opening will typically have a high aspect ratio, for example, greater than 2:1 and typically greater than 4:1.

Copper and other non-noble metals exposed in the insulating layer are normally covered by organic contamination as well as a thin layer of metal oxide after they have been exposed to the ambient atmosphere. These layers can interfere with the subsequent steps of this invention. Thus if the metal layers have been exposed to the atmosphere, the organic contamination and native oxide should be removed as a first step. Organic contamination of the surface may be removed by oxidation with an oxygen plasma, or with UV light and ozone. A variety of methods are known to remove the native oxide from metal surfaces, including etching, reduction, physical bombardment by plasmas, etc. In clean environments, e.g., in clean room environments typically employed in semiconducting manufacturing processes, preliminary cleaning may not be necessary or advantageous.

In the case of copper, the copper oxide may be removed by an etchant selected from the group comprising beta-diketones, beta-ketimines and amidines. In a preferred embodiment the etchant is the vapor of the fluorinated beta-diketone, 1,1,1,5,5,5-hexafluoro-2,4-pentanedione (Hfac), preferably heated to temperature of 150° C. or more to obtain useful etching rates. Etching of copper oxide at still lower temperatures, down to about 100° C., can be carried out by simultaneous reaction with the vapors of Hfac and a neutral complexing agent such as tert-butylisonitrile. Alternatively, copper oxide can be dissolved by weak aqueous acids, such as acetic acid. Preferably, dissolved oxygen may first be removed from the acid solution, so that the underlying copper is not etched at the same time. Aqueous removal may not be so convenient when porous dielectric materials are also present because the pores may adsorb the solution, which may then be difficult to remove. Another consideration with aqueous acid etching is that even a brief exposure to air will quickly re-form a thin oxide layer. Such re-oxidation would occur between the removal of the substrate from the acid solution and its placement into a vacuum chamber for the subsequent steps. Because of these considerations with aqueous acid etching, preferred embodiments using vapor-etching processes for the removal of oxide from copper may be performed.

Copper oxide on the surface of the copper may also be removed by reduction to copper metal. Examples of reducing agents include hydrogen atoms (H plasma), hydrogen gas (H₂), trioxane, formaldehyde, gloxylic acid, acetic acid, formic acid, other organic acids, alcohols, aldehydes and ketones. Reduction with a hydrogen plasma is facilitated by heating the oxidized copper to a temperature above about 20° C. Reduction with formic acid may require heating to a temperature around 100° C. For the other molecular reducing agents, heating to around 300° C. may be necessary to complete the reduction.

Similar cleaning steps may be applied if the exposed metal is cobalt, ruthenium or other metals.

2. Passivating the Metal Surfaces—Process Step 220.

Next the clean metal surfaces are covered with a material that presents an inert surface to the subsequent process step. At the same time, the chemistry of this protection process is designed to avoid reaction with insulators. Inert surfaces may be provided by alkyl groups or fluoroalkyl groups. Thus, in one embodiment, a clean copper surface is protected by covering the copper surface with alkyl or fluoroalkyl groups, without transforming insulator surfaces.

One method for such a selective passivation of metal surfaces is provided by alkylthiols or fluoroalkylthiols. These materials are known to react with many clean metal surfaces, such as copper, to produce a surface densely covered by alkyl or fluoroalkyl groups. At the same time, alkylthiols or fluoroalkylthiols show little or no reactivity with silica surfaces. Dialkyldisulfides show a similar selective reactivity to copper. Likewise, diazoalkanes such as diazomethane are selectively polymerized by a copper surface into a polyalkane coating. Alkylisonitriles are strongly and selectively attached to noble metals such as ruthenium and platinum.

Although these passivating agents can be applied to the surfaces in liquid solution, the liquid agent may be absorbed by a porous insulator. In a preferred embodiment, the surfaces of the microelectronic device are exposed to vapors of one or more of passivating agents; only the metal surfaces are reactive with the vapors and the insulating surfaces are unaffected. Selective reaction with metal surfaces can thus be achieved without significant change to porous low-k dielectrics.

3. Selective Deposition of Aluminum or Other Lewis Acid Catalysts—Process Step 230.

In the next step, a catalyst is applied selectively to the insulating areas, while leaving the protected metal areas unchanged. The catalyst is typically a Lewis acid that adheres to the exposed surfaces of the insulator, including the surface pores. In some embodiments, aluminum amides are used for forming Lewis acidic aluminum sites, which catalyze the growth of silica in the following step. Some examples of suitable aluminum amides are given in Table 1, along with references to their synthesis and commercial sources for the compounds.

TABLE 1
Some Volatile Aluminum Amides

| | Melting | Vapor | |
|---|---|---|---|
| | point | pressure | |
| Compound | ° C. | ° C./Torr | References and commercial sources |
| Al(N(SiMe₃)₂)₃ | 188 | | Wannagat, J. Organomet. Chem. 33, 1 (1971) |
| Al₂(NEt₂)₆ | liquid | | S. Barry & R. G. Gordon, U.S. Pat. No. 6,969,539 |
| Al₂(NEtMe)₆ | liquid | 100/0.25 | S. Barry & R. G. Gordon, U.S. Pat. No. 6,969,539 |
| Al(N¹Pr₂)₃ | 56-59 | | Brothers, Organometallics 13, 2792 (1994) |
| Al₂(NMe₂)₆ | 88-89 | 90/0.1 | Ruff, JACS 83, 2835 (1961); Aldrich |
| Al(N(Et)CH₂CH₂NMe₂)(NMe₂)₂ | liquid | 65-70/0.3 | Barry, Gordon & Wagner, Mat. Res. Soc. |
| | | | Symp. Proc. 606, 83-89 (2000) |

where
Me = methyl;
Et = ethyl; and
¹Pr = isopropyl.

In at least some embodiments, aluminum alkyls are useful in the practice of this invention. Some examples are given in Table 2.

TABLE 2
Some Volatile Organoaluminum Compounds

| | Melting | Vapor | |
|---|---|---|---|
| | point | pressure | |
| Compound | ° C. | ° C./Torr | Commercial sources |
| AlMe₃ | 15.4 | 20/8 | Albemarle, Aldrich, Strem |
| AlEt₃ | −50 | 129/50 | Albemarle, Aldrich, Alfa, Strem |
| Al(¹Bu)₃ | 5 | 86/10 | Albemarle, Aldrich, Alfa, Strem |

where
Me = methyl;
Et = ethyl; and
¹Bu = isobutyl.

In at least some embodiments, aluminum alkoxides can be used in the practice of this invention. Suitable compounds are listed in Table 3.

TABLE 3
Some Volatile Aluminum Alkoxides

| | Melting | Vapor | |
|---|---|---|---|
| | point | pressure | References and |
| Compound | ° C. | ° C./Torr | commercial sources |
| Al₂Et₃(O-sec-Bu)₃ | liquid | 190/0.1 | Strem |
| Al(O¹Pr)₃ | 140 | 140.5/8 | Aldrich, Alfa, Gelest, |
| | | | Strem |
| Al₂Me₄(O-¹Pr)₂ | liquid | 70/10 | Mole, Australian |
| | | | J. Chem. 19, 373 (1966) |

where
Me = methyl;
¹Pr = isopropyl; and
sec-Bu = sec-butyl.

Aluminum halides, such as aluminum chloride, may also be used in the practice of this invention, but they have the potential disadvantages that they tend to leave some halide impurity in the film and cause corrosion of substrates or apparatus.

The aluminum precursors generally react with oxygen or moisture in the ambient air, and should be stored under an inert, dry atmosphere such as pure nitrogen gas.

In addition, other metals having a Lewis acid character may be used in the practice of this invention. For example, compounds that contain a Lewis acid metal including, but not limited to, magnesium, boron, scandium, lanthanum, yttrium, titanium, zirconium, and hafnium, are within the scope of this invention.

The exposure of metal catalyst precursor delivered in this step is preferably small enough to deposit catalyst only on the surfaces of the outer pores in a porous dielectric material, while the inner pores remain uncoated with the catalyst. The exposure to the metal precursor desirably is also large enough to penetrate to the bottom of the vias and trenches, which typically have aspect ratios up to about 4:1. Thus in an exemplary embodiment, the metal catalyst penetrates about 4 pore diameters deep into pores near the tops of the trenches, while only reaching into the outermost pore regions near the via and trench bottoms. Exposure is defined as the product of the partial pressure of the catalyst precursor and the time that its vapor spends over the top opening of a trench or via. For trimethylaluminum as an aluminum catalyst, exemplary exposures to reach a 4:1 aspect ratio are about 0.015 Pascal-seconds or 1.1×10⁻⁴ Torr-seconds, assuming that the trimethylaluminum vapor is monomeric at a reaction temperature of 250° C. Exposures for other aspect ratios, precursors or temperatures can be calculated from formulas given in the article “A Kinetic Model for Step Coverage by Atomic Layer Deposition in Narrow Holes or Trenches,” by Gordon et al., in Chemical Vapor Deposition, volume 9, pages 73-78 (2003), which is hereby incorporated by reference, or by other conventional techniques.

4. Catalytic Deposition of Silica Films—Process Step 240.

A silica layer is deposited by reaction of a vapor of a silanol with the catalytic areas of the heated substrate. Suitable silanol compounds for use in the practice of the present invention are provided in Patent Application WO03083167 and in U.S. Pat. No. 6,969,539, which are hereby incorporated in their entirety by reference.

In at least some embodiments, tris(alkoxy)silanol compounds, as discussed herein, have the general formula 1, in which R¹ through R⁹ represent hydrogen, alkyl groups, fluoroalkyl groups, alkenyl groups, alkynyl groups, aryl groups or alkyl, alkenyl, alkynyl or aryl groups substituted with other non-metallic atoms or groups, such as alkylsilyl or alkylamino groups, preferably selected to maintain the volatility of the compound, where any one of R¹ through R⁹ is the same or different from each other. In other embodiments, R¹ through R⁹ may include groups having some degree of unsaturation, such as aryl, alkenyl and alkynyl groups. R¹ through R⁹ may also include alkyl silyl or alkylamino groups. In one or more embodiments, Rⁿ are lower alkyl groups containing 5 or less carbons. In one or more embodiments, Rⁿ are a mixture of hydrogen and lower alkyl groups.

In some embodiments, the groups R¹ through R⁹ contain between one and four carbons and are the same or different.

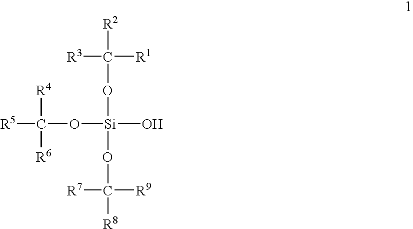

In at least some embodiments methyl groups are selected for each of the R¹ through R⁹ in the general formula 1 given above, obtaining the compound tris(tert-butoxy)silanol 2, which may be written more compactly as (Bu^{t}O)₃SiOH.

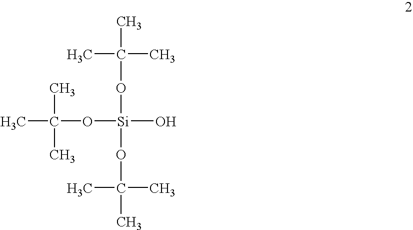

Another compound of the invention is the liquid tris(tert-pentyloxy)silanol, also known as tris(tert-amyloxy)silanol 3, which may be written more compactly as (Am^{t}O)₃SiOH.

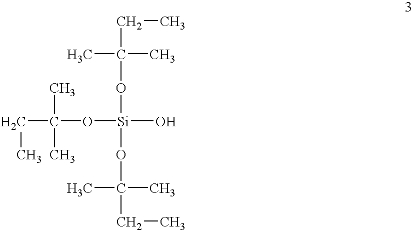

In at least some embodiments of the invention di(alkoxy)silanediols such as (Bu^{t}O)₂Si(OH)₂ can also be used, although they are less stable than tris(alkoxy)silanol compounds in at least some applications. Di(alkoxy)silanediol compounds having the general formula 4 may be used according to the invention, in which any of R¹ through R⁶ represent hydrogen, alkyl groups, fluoroalkyl groups, alkenyl groups, alkynyl groups, aryl groups or alkyl, alkenyl, alkynyl or aryl groups substituted with other non-metallic atoms or groups, such as alkylsilyl or alkylamino groups, preferably selected to enhance volatility and stability, and which may be the same or different.

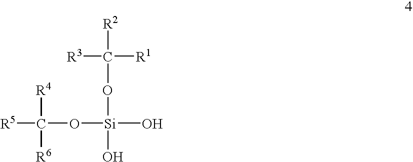

In other embodiments, R¹ through R⁶ may include groups having some degree of unsaturation, such as aryl, alkenyl and alkynyl groups. R¹ through R⁶ may also include alkyl silyl or alkylamino groups. In one or more embodiments, Rⁿ are lower alkyl groups containing 5 or less carbons. In one or more embodiments, Rⁿ are a mixture of hydrogen and lower alkyl groups.

In other embodiments di(alkoxy)alkylsilanols having the general formula 5 are used (where R¹ through R⁶ may be as described above for formula 4), particularly in making films with dielectric constants lower than silica because the alkyl groups R⁷ may be retained in the deposited film.

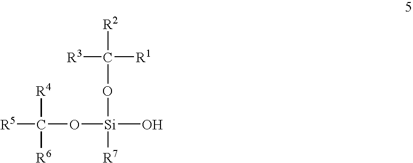

In at least some embodiments, the groups R¹-R⁹ for the general formula 1, R¹-R⁶ for the general formula 4 or R¹-R⁷ for the general formula 5 may be selected from the group consisting of hydrogen, methyl, ethyl, n-propyl or isopropyl groups.

In the foregoing compounds, it is also understood that alkyl groups R¹ through R⁹ for general formula 1, R¹ through R⁶ for general formula 4 or R¹ through R⁷ for the general formula 5 may be a hydrocarbon having some degrees of unsaturation, e.g., aryl, alkenyl or alkynyl groups.

Silanols are generally stable and non-reactive to air and water. Silanol and silanediol reactants are commercially available or may be prepared using conventional or known techniques. Two silanols, tris(tert-butoxy)silanol, and tris(tert-pentoxy)silanol, are commercially available from Aldrich Chemical Company (Milwaukee, Wis.), Gelest, Inc. (Tullytown, Pa.) and Air Products, Inc. (Allentown, Pa.). Tris(tert-butoxy)silanol may be prepared as follows. First, tris(tert-butoxy)chlorosilane may be prepared by either of the following two reactions:
SiCl₄+3Bu^{t}OH→(Bu^{t}O)₃SiCl+3HCl (1)
SiCl₄+3NaOBu^{t}→(Bu^{t}O)₃SiCl+3NaCl (2)

The tris(tert-butoxy)chlorosilane is then hydrolyzed according to the reaction
(Bu^{t}O)₃SiCl+H₂O→(Bu^{t}O)₃SiOH+HCl (3)

See, Backer et al., Rec. Trav. Chim., 61:500 (1942). This hydrolyzed compound, tris(tert-butoxy)silanol, is a solid at room temperature and melts at about 66° C. It sublimes at room temperature at a low pressure of about 10⁻⁴ Torr, and can be distilled at a temperature of about 104° C. at a pressure of 20 Torr. It is highly soluble in organic solvents such as mesitylene or tetradecane, so that its vapors can also be formed conveniently by flash vaporization of its solution.

As would be appreciated by one of ordinary skill in the art, other tris(tert-alkoxy)silanols may be prepared by similar reactions, by substituting other tertiary alcohols, such as tert-pentyl alcohol (also known as tert-amyl alcohol), for tert-butanol. Tris(tert-amyloxy)silanol, (Am^{t}O)₃SiOH, (also called tris(tert-pentoxy)silanol) is a liquid at room temperature, so its vapors can be formed conveniently by flash vaporization of the neat liquid. It has a vapor pressure of about 2 Torr at 96° C.

Tris(tert-alkoxy)silanol or bis(tert-alkoxy)silanediol vapors may be reacted with a suitably reactive vapors of one or more aluminum compounds to deposit a solid film comprising silicon, aluminum and oxygen. Generically, (alkoxy)silanols and (alkoxy)silanediols such as tris(tert-alkoxy)silanols or bis(tert-alkoxy)silanediols are referred to as “silanols.”

Also included in the general class of “silanols” are compounds in which a tert-alkoxy group in a tris(tert-alkoxy)silanol or bis(tert-alkoxy)silanediol is replaced by an alkyl group or a substituted alkyl group such as a partially fluorinated alkyl group. Silanols with an alkyl group directly bound to the silicon bring that alkyl group into the deposited film, giving it properties that are desirable in some applications, such as low dielectric constant, low refractive index and low stress. For example, bis(tert-butoxy)alkylsilanols can be prepared starting with either of the following two reactions:
RSiCl₃+2Bu^{t}OH+2base→(Bu^{t}O)₂RSiCl+2HCl-base (4)
RSiCl₃+2NaOBu^{t}→(Bu^{t}O)₂RSiCl+2NaCl (5)
followed by hydrolysis of the chloride:
(Bu^{t}O)₂RSiCl+H₂O→(Bu^{t}O)₂RSiOH+HCl (6)

See, H.-J. Holdt et al., Z. Chem, 23:252 (1983) for a description of these reactions. Bis(tert-butoxy)methylsilanol prepared in this way has a vapor pressure 32 Torr at a temperature of 87° C.

5. Optional Final Cleaning of the Copper—Process Step 250.

After the previous steps are completed, the copper surfaces may be cleaned to allow low-resistance contact of with the next layer of copper to be deposited. This cleaning is designed to remove the capping layer, along with any small amount of silica on the copper. Any traces of silica on the surface may be removed by reactive ion etching, or by treatment with a fluorine-containing plasma. Then a thiol capping layer may be removed with a hydrogen plasma or by oxidants such as oxygen, ozone or an oxygen-containing plasma.

Additional post-processing steps are contemplated. For example, a diffusion barrier layer may be deposited to reduce the migration of metal ions, e.g., copper ions, into the surrounding silica layer. Deposition of diffusion barrier layers is known in the art and conventional processing methods may be used. For example, ALD and CVD have been used. See, U.S. Pat. No. 6,852,635 and W. Besling et al. in Atomic Layer Depositin of Barriers for Interconnects, International Interconnect Technology Conference 2002, which are hereby incorporated in their entirety be reference.

6. Applying the Reactant Vapors

Vapors of liquid precursors may be formed by conventional methods, including heating in a bubbler, in a thin-film evaporator, or by nebulization into a carrier gas preheated to about 100 to 200° C. The nebulization may be carried out pneumatically, ultrasonically, or by any other another suitable method. Solid precursors may be dissolved in organic solvents, including hydrocarbons such as decane, dodecane, tetradecane, toluene, xylene and mesitylene, and with ethers, esters, ketones and chlorinated hydrocarbons. Solutions of liquid precursors generally have lower viscosities than the pure liquids, so that at least some embodiments nebulize and evaporate solutions rather than the pure liquids. The liquids or solutions may also be evaporated with thin-film evaporators or by direct injection of the liquids into a heated zone. Commercial equipment for vaporization of liquids is made by MKS Instruments (Andover, Mass.), ATMI, Inc. (Danbury, Conn.), Novellus Systems, Inc. (San Jose, Calif.) and COVA Technologies (Colorado Springs, Colo.). Ultrasonic nebulizers are made by Sonotek Corporation (Milton, N.Y.) and Cetac Technologies (Omaha, Nebr.).

In one embodiment of the invention, the process is carried out using 6-port sampling valves (Valco model EP4C6WEPH, Valco Instruments, Houston, Tex.), normally used for injecting samples into gas chromatographs, to deliver pulses of liquids or solutions into a suitable carrier gas. Each time that a valve is opened, solution flows into a tube in which solution is vaporized by heat from hot oil flowing over the outside of the tube. Carrier gas moves the vapor from the tube into a heated reactor tube.

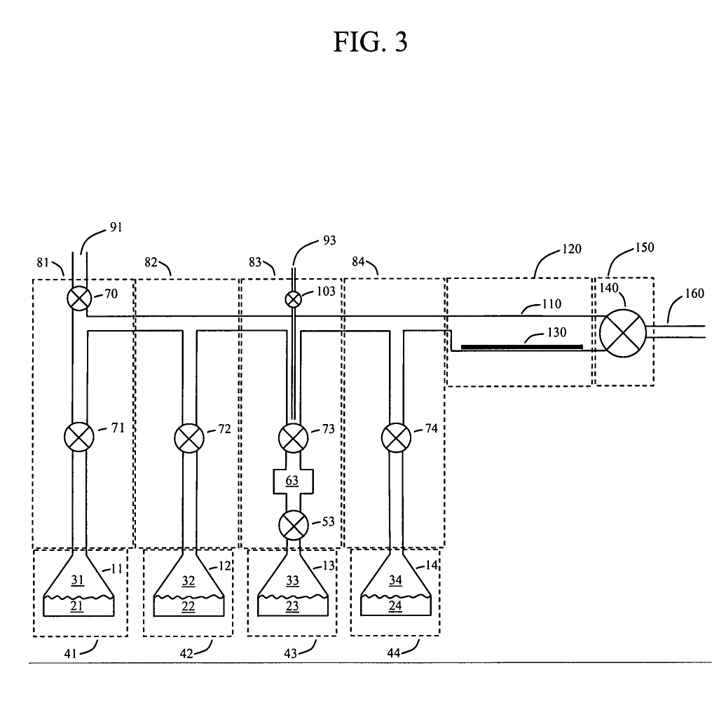

In another embodiment, a silica layer is deposited selectively using an apparatus such as that illustrated in FIG. 3. After UV-ozone cleaning, the substrate 130 is placed into chamber 110, which is evacuated through pipe 160 into a trap and vacuum pump (not shown).

a) Furnace 120 is heated to a temperature suitable for reduction of the metal oxide (typically about 300° C.). After this temperature is reached, valve 140 is closed. Vapor 31 of the reducing agent 21 is introduced into the heated chamber 110 by opening an air-actuated diaphragm valve, 71 (Titan II model made by Parker-Hannifin, Richmond Calif. or ALD valve made by Swagelok, Willoughby, Ohio). After allowing a short time for flow of the vapor, valve 71 is closed. A suitable time is allowed for reduction of the metal oxide to a clean metal surface. Then chamber 110 is evacuated and finally valve 140 is closed.

b) The temperature in furnace 120 is adjusted to a value suitable for reaction of the protective agent with the metal surface (typically about 120° C.). Vapor 32 of the protective agent 22 is introduced into the heated chamber 110 by the use of an air-actuated diaphragm valve, 72. After allowing a short time for flow of the vapor, valve 72 is closed. A suitable time is allowed for the vapor of the protective agent to react with the metal surface. Then chamber 110 is evacuated and finally valve 140 is closed.

c) The temperature in furnace 120 is adjusted, if necessary, to a value suitable for reaction of the catalyst agent with the insulating surface (typically about 120° C.). Valves 70 and 103 are opened so that carrier gas flows from sources 91 and 93 (not shown). Vapor 33 of the catalyst precursor 23 is introduced into the heated chamber 110 by the use of an air-actuated diaphragm valve, 73. After allowing a short time for flow of the vapor, valve 73 is closed. A suitable time is allowed for the vapor of the catalyst precursor to react with the insulating surface. Valves 90 and 103 are then closed. The exposure (equal to the product of the reaction time and the partial pressure of the catalyst precursor) is limited so that only the surface pores are coated while the inner pores remain uncoated with the catalyst. Then chamber 110 is evacuated and finally valve 140 is closed.

d) The temperature in furnace 120 is adjusted to a value suitable for reaction of the silanol with the insulating surface (typically about 240° C.). Vapor 34 of the silanol 24 is introduced into the heated chamber 110 by the use of an air-actuated diaphragm valve, 74. After allowing a short time for flow of the vapor, valve 74 is closed. A suitable time is allowed for the vapor of the silanol to react with the catalytically activated insulating surface. The exposure to the silanol is chosen to be large enough to seal the largest pores on the surface of the dielectric. Then chamber 110 is evacuated and finally valve 140 is closed.

e) Optionally, any residual silica on the metal surface may be removed by bombardment with reactive fluorine-containing ions directed at the metal surface, in chamber 130 or elsewhere. A thiol capping layer may be removed by treatment with a hydrogen-containing plasma, an oxygen-containing plasma, or by heating in the presence of oxygen or an oxidizing agent.

The present invention provides materials and processes for producing superior dielectric materials possessing desired low density and low-k characteristics without certain processing problems associated with porosity of the dielectric material. Specifically, using the deposition processes of the invention, surface porosity of the porous dielectric material is significantly reduced or eliminated while internal porosity is preserved to maintain a desired low-k value for the overall dielectric material.

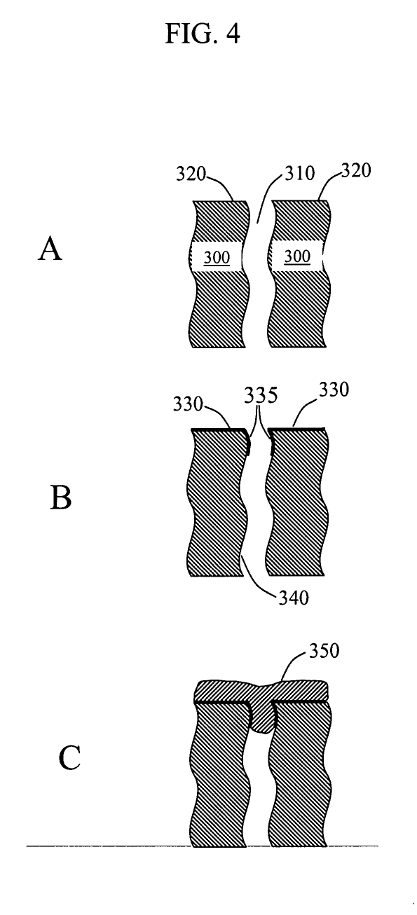

The steps in carrying out this sealing process may be understood better by reference to FIG. 4. FIG. 4A shows a schematic cross-section of material 300 having pores such as the one denoted by 310. In carrying out this sealing process, the surface pores of a porous dielectric material are sealed with a second insulating material 350 such as silica or other insulating or low-k material without filling the interior spaces of the pores, as is shown in FIG. 4C. To seal off these surface pores of a porous dielectric, thin catalytic layers 330 and 335 are first deposited on the surface and the pore sidewalls that are proximal to the surface, as illustrated in FIG. 4B. Note that the catalytic layers extend only a short distance into the pore. The catalytic material can be an aluminum-containing material that is deposited in a process that has low step coverage (e.g. non-conformal coating of the sidewalls and any interior space or surface of the pores or trenches). In this way the catalytic layer 330 is deposited on the outer surface 320 of the porous material and as a layer 335 on the inner surface of pores just near to the surface. The deeper interior surfaces 340 of the pores are left free of catalyst.

As would be appreciated by one of skill in the art, such low step coverage may readily be obtained by adjusting the reaction conditions and reactant reactivity. For instance, vapor deposition may be utilized under conditions where the exposure of the vapor to the substrate surface is brief, the dose of reactants is limited, and high vacuum pumping speed is used to limit the penetration of the reactant materials to the portions of the pores near the surface (e.g., where the pores are defined by at least one sidewall and an interior space, the penetration is controlled such that only the top portions of the sidewalls are coated with the reactants).

In certain embodiments, the present invention is directed to depositing coatings, particularly those made predominantly of silicon dioxide, on a porous substrate. In certain embodiments, these coatings comprise silicon dioxide, relatively small amounts of aluminum, and optionally, may contain carbon and hydrogen, and relatively small amounts of other elements (e.g., dopants). For example, one dose of a silanol precursor is supplied to a porous substrate previously coated with a catalyst as in FIG. 4B. This process allows for the formation of enough low-k material 350 to fill the surface pores, while no low-k material is formed on the interior surfaces of the pores that lack the aluminum oxide catalyst or on the metal surfaces protected with a capping layer. Using this method, even large surface pores are filled by one dose of silanol. For example, if tris(tert-butoxy)silanol, (Bu^{t}O)₃SiOH, is used, then pores up to 30 nm diameter can be completely filled in one dose. Since pores in typical ultralow-k dielectric materials are not more than 10 nm in diameter, there is an adequate safety margin so that even a few excessively large pores would be filled. Methylbis(tert-butoxy)silanol, Me(Bu^{t}O)₂SiOH, could be used to fill the surface pores with a material that has a lower dielectric constant than silica.

Although the invention is not bound by theory or mode of operation, it is proposed that certain chemical reactions occur during the process of the invention. First the copper surface is reduced to pure copper, which then reacts with the thiol vapor, which largely protects the copper surface from subsequent reaction with the aluminum precursor.

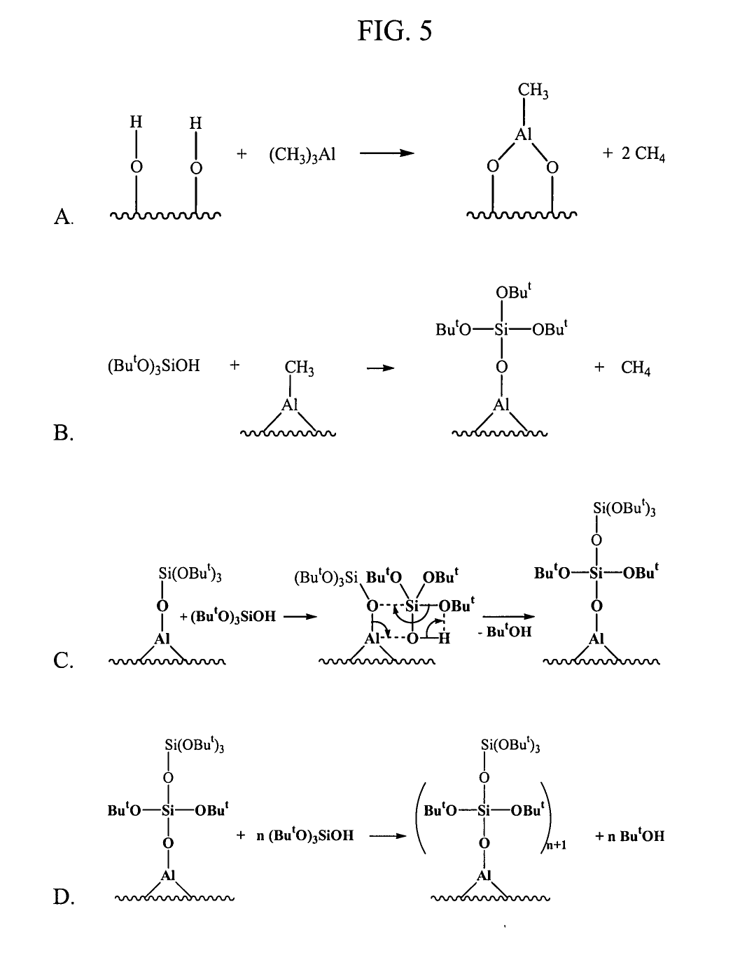

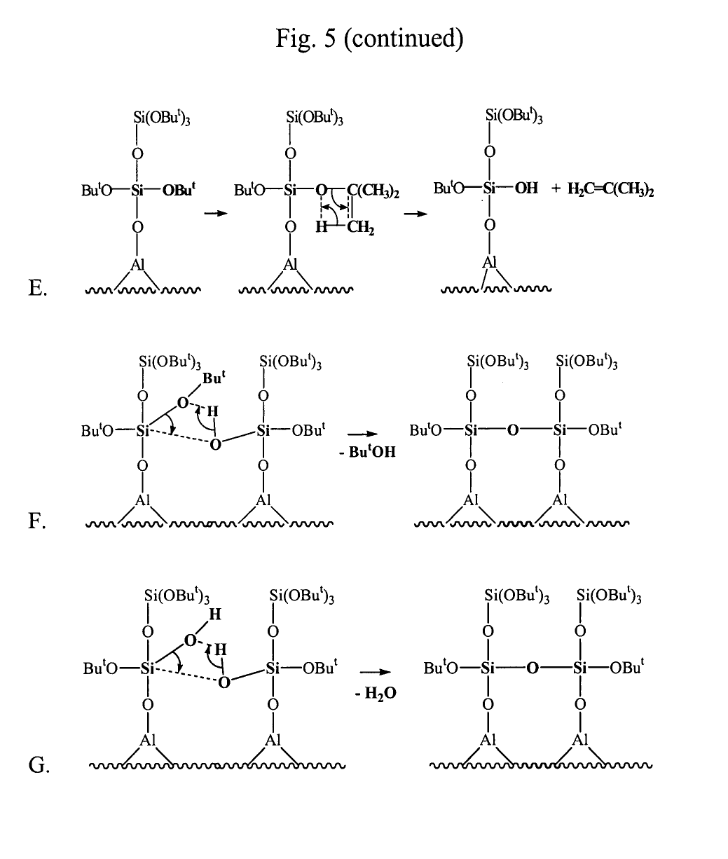

In order to form catalytic sites on the surface of the porous low-k material, trimethylaluminum reacts with a hydroxylated surface by reactions such as the one shown in FIG. 5A, resulting in chemisorption of aluminum and elimination of byproduct methane gas. During the second half-reaction, tris(tert-butoxy)silanol, (Bu^{t}O)₃SiOH (abbreviated as “silanol”), reacts with the methylaluminum-containing surface left from the first half-reaction; the silanol becomes chemically bound to the surface and eliminates methane by reactions such as the one shown in FIG. 5B. An additional silanol molecule then diffuses up to the surface and inserts into an aluminum-oxygen bond by the concerted mechanism sketched in FIG. 5C. Repeated insertions of silanols into the Al—O bond form a siloxane polymer bound to the surface through the aluminum, which catalyzes this polymerization, as indicated in FIG. 5D. The presence of the thiol on the metal surfaces reduces or eliminates the reactive sites for the attachment of the aluminum compound.

This siloxane polymer is attached to the surface by strong chemical bonds and therefore is non-volatile; thus, it is postulated that the conversion of the volatile silanol to non-volatile siloxane polymer is an irreversible chemisorption process. Because the silanol can diffuse through this soft surface-bound siloxane polymer, the catalytic aluminum atoms remain available to catalyze the polymerization of more silanol molecules. The rate-limiting step in this process is the catalytic conversion of silanol to siloxane, provided that the concentration of silanol vapor is high enough to keep the catalytic aluminum centers fully occupied; thus, the chemisorption rate does not depend on the rate at which silanol arrives at the surface of the siloxane layer. In the language of chemical kinetics, the chemisorption rate is zero-order in the vapor concentration of silanol. This condition is important in making uniformly thick films, regardless of, and independent of any non-uniformities that may exist during the distribution of silanol vapor over the surface.

The tert-butyl groups on the siloxane decompose thermally by β-hydrogen elimination of isobutene, leaving hydroxyl groups on the silicon, as indicated in FIG. 5E. A newly-formed hydroxyl group may transfer a hydrogen atom to a nearby butoxy group, eliminating tert-butanol and cross-linking the silicon atoms by an oxygen atom, by reactions such as the one drawn in FIG. 5F. This cross-linking may also be achieved by elimination of water between two adjacent hydroxyl groups, as in FIG. 5G. These cross-linking reactions connect the siloxane polymer chains, causing the polymer layer to gel and eventually solidify to silica (SiO₂). Because the silanol presumably has a negligible rate of diffusion through solid silica, additional silanol can no longer reach the catalytic aluminum atoms, so the chemisorption of silanol finally stops (becomes self-limited).

The invention may be understood with reference to the following examples which are for the purpose of illustration only and which are not limiting of the invention, the full scope of which is set forth in the claims which follow.

### EXAMPLE 1

### Selective Deposition of Silica

A substrate containing holes in porous silica 0.4 μm deep and 0.13 μm in diameter was prepared with copper at the bottoms of the holes.

a) Cleaning was carried out by UV-ozone to remove hydrocarbon contamination from the surfaces. It was then placed within the apparatus shown schematically in cross section in FIG. 3, and heated to 300° C. During the heating, water vapor previously adsorbed into the pores of the porous dielectric was allowed to escape into the vacuum. Solid trioxane, (CH₂O)₃, 21 was contained in vessel 11 at room temperature. Valve 71 was opened to allow vapors 31 of trioxane 21 to enter the chamber, where they reduced the copper oxide on the surface to clean copper metal over a period of 10 minutes. Then the temperature in furnace 120 was decreased to 120° C. Valve 71 was then closed. Valve 140 was opened to the vacuum pump and valve 70 was opened to nitrogen source 91 (not shown) to purge the trioxane vapor from chamber 110 for 1 minute. Then valve 70 was closed to stop the flow of nitrogen. Chamber 110 was evacuated for 1 minute more until valve 140 was closed.

b) Liquid 1H,1H,2H,2H-perfluorodecyl-1-thiol, CF₃(CF₂)₅CH₂CH₂SH, (“thiol”) 22 was held in reservoir 12 at room temperature. Valve 72 was opened for ½ hour to allow thiol vapor 32 to fill chamber 110. During this exposure to the thiol vapor 33, the copper parts of the surface of substrate 130 became covered with a fluoroalkane layer. Valve 72 was then closed. Valve 140 was opened to the vacuum pump and valve 70 was opened to nitrogen source 91 (not shown) to purge the thiol vapor from chamber 110 for 1 minute. Then valve 70 was closed to stop the flow of nitrogen and chamber 110 was evacuated for 1 minute.

c) Liquid trimethylaluminum (“TMA”) 23 in container 13 was held in an ice-bath 43 at 0° C. Valves 70 and 103 were opened so that nitrogen gas flowed from sources 91 and 93 (not shown). To deliver a pulse of TMA vapor, valve 53 was opened 1 second to allow TMA vapor to fill the evacuated reservoir 63. Valve 103 was opened to allow gas from nitrogen source 93 (not shown) to flow through chamber 110 into the vacuum pump. Then valve 73 was opened for one second to allow a brief exposure of TMA vapor to the substrate 130. Then the excess TMA vapor was removed by allowing the nitrogen purge to continue for another 15 seconds, after which valves 70 and 103 were closed.

d) Molten tris(tert-butoxy)silanol (“silanol”) 24 in a stainless steel container 14 was held in oven 44 at a temperature of 120° C. The temperature of the chamber 110 was increased to 250° C. Then valve 140 was closed to separate the evacuated chamber 110 from the vacuum pump. To deliver silanol vapor, valve 74 was opened for 1 second to fill chamber 110 with silanol vapor at its equilibrium vapor pressure. Then valve 74 was closed. After 15 seconds, valve 140 between the vacuum pump and the chamber 110 was opened.

e) The furnace 120 was cooled down to room temperature. Then a hydrogen plasma was applied for 20 minutes to remove the thiol capping layer.

The surface of a witness silicon substrate was examined by ellipsometry and found to have a silica film with uniform thickness of 6 nm. Considering that the silicon substrate had a native silica film about 1 nm thick on it before deposition, the process deposited about 5 nm of silica on this flat surface. X-ray photoelectron spectroscopy (XPS) of a copper surface showed that only about 0.5 nm of silica had been deposited on it. Cross-sectional transmission electron micrograph (TEM) images confirmed the selective deposition of about 8 nm of silica on the porous low-k material, along with minimal material on the copper. The higher growth rate of the silica on porous low-k presumable arises from the greater surface area on the rough surface of the porous low-k, which adsorbs a greater area density of aluminum catalyst than a flat surface does.

### EXAMPLE 2

Example 1 was repeated with tris(tert-pentyloxy)silanol vapor in place of the tris(tert-butoxy)silanol vapor. Results similar to those of Example 1 were obtained.

### EXAMPLE 3

Example 1 was repeated, except that hexakis(dimethylamido)dialuminum vapor was used in place of the trimethylaluminum vapor. The molten hexakis(dimethylamido)dialuminum was heated to 120° C. to produce its vapor. Results similar to those of Example 1 were obtained except that the silica thicknesses were slightly lower.

### COMPARATIVE EXAMPLE 1

Example 1 was repeated using only the silicon and oxygen precursor, tris(tert-butoxy)silanol, and no aluminum precursor. No film was observed to have been deposited on the substrate surfaces.

### COMPARATIVE EXAMPLE 2

Example 1 was repeated using only the aluminum precursor, trimethylaluminum, and no silicon precursor. A very small amount of aluminum oxide, about 0.1 nm thick, was found on silica surfaces, but no film was found on copper surfaces.

### COMPARATIVE EXAMPLE 3

Example 3 was repeated using only the aluminum precursor, hexakis(dimethylamido)dialuminum, and no silicon precursor. No film was detected.

### COMPARATIVE EXAMPLE 4

Example 1 was repeated using the tetrakis(tert-butoxy)silane in place of the tris(tert-butoxy)silanol. No film was detected. This example illustrates that the reactivity of the silicon precursor depends on the presence of the silanol (—OH) group.

Those skilled in the art will recognize or be able to ascertain using no more than routine experimentation, many equivalents to the specific embodiments of the invention described specifically herein. Such equivalents are intended to be encompassed within the scope of the following claims.

What is claimed is:

1. A method of selectively depositing a silica layer on a substrate, comprising:
exposing a substrate comprising metallic and non-metallic surfaces to a protecting agent that interacts selectively with the metallic surface to deposit a protective layer on at least a portion of the metallic surface;
exposing the protected substrate to a catalytic agent that interacts selectively with the non-metallic surfaces to form a catalytic surface on at least a portion of the non-metallic surface; and
exposing the substrate to a silanol vapor to form a silica layer only on the catalytic surface of the substrates.

2. The method of claim 1 wherein said catalytic agent comprises aluminum metal or an aluminum-containing compound.

3. The method of claim 2, wherein the protected substrate is exposed to vapor of an aluminum-containing compound.

4. The method of claim 2 or 3, wherein the aluminum metal or aluminum-containing compound is selected from the group comprising aluminum alkyls, aluminum dialkylamides, aluminum alkoxides and their mixtures or reaction products.

5. The method of claim 4, wherein the aluminum metal or aluminum-containing compound is selected from the group comprising trimethylaluminum, aluminum tris(dimethylamide) and dimethylaluminum isopropoxide.

6. The method of claim 1, wherein the catalytic agent is a metal or metalloid compound selected from the group consisting of metal and metalloid amides, amidinates, alkyls, alkoxides and halides.

7. The method of claim 6, in which the metal or metalloid is selected from the group consisting of aluminum, boron, magnesium, scandium, lanthanum, yttrium, titanium, zirconium and hafnium.

8. The method of claim 1, wherein the silanol has the formula 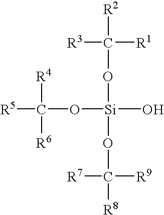
where R¹ through R⁹ inclusive represents hydrogen, alkyl groups, fluoroalkyl groups, alkenyl groups, alkynyl groups, aryl groups or alkyl, alkenyl, alkynyl or aryl groups substituted with other non-metallic atoms or groups, and R¹ though R⁹ are the same or different.

9. The method of claim 1, wherein the silanol has the formula 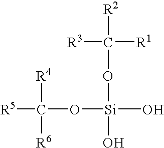
where R¹ through R⁶ inclusive represents hydrogen, alkyl groups, fluoroalkyl groups, alkenyl groups, alkynyl groups, aryl groups or alkyl, alkenyl, alkynyl or aryl groups substituted with other non-metallic atoms or groups, and R¹ though R⁶ are the same or different.

10. The method of claim 1, wherein the silanol has the formula 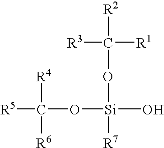
where R¹ through R⁷ inclusive represents hydrogen, alkyl groups, fluoroalkyl groups, alkenyl groups, alkynyl groups, aryl groups or alkyl, alkenyl, alkynyl or aryl groups substituted with other non-metallic atoms or groups, and R¹ though R⁷ are the same or different.

11. The method of claim 8, wherein the groups R¹ through R⁹ contain between one and four carbons and are the same or different.

12. The method of claim 1, in which exposure of the substrate to a protective agent does not significantly reduce the reactivity of the non-metallic surface to the catalytic agent.

13. The method of claim 1, wherein the protective agent is selected from the group consisting of alkylthiols, dialkyldisulfides, alkylisonitriles, diazoalkanes, and fluorinated derivatives thereof.

14. The method of claim 1, further comprising cleaning the surfaces of the substrate prior to processing.

15. The method of claim 14, in which cleaning comprises oxidation followed by reduction or removal of the metal oxide.

16. The method of claim 15, in which the oxidation comprises exposure to one or more members of the group comprising an oxygen-containing plasma, ultraviolet light and ozone.

17. The method of claim 15, in which the reduction or removal step comprises exposure to one or more members of the group comprising a hydrogen plasma, hydrogen, trixoane, alcohols, ketones, aldehydes, organic acids, beta-diketones, beta-ketimines, amidines and isonitriles.

18. The method of claim 1, further comprising removing the protective layer and any residual silica from the metal surfaces after silica formation.

19. The method of claim 18, in which removing residual silica comprises reactive ion etching, a fluorine-containing plasma or a vapor etch comprising hydrogen fluoride.

20. The method of claim 15, in which the protective layer is removed with a hydrogen plasma.

21. The method of claim 1, wherein the silica layer is deposited at a thickness of at least 2 nm.

22. The method of claim 1, further comprising depositing a diffusion barrier layer on the silica layer.

23. A method of forming a silica layer selectively on the surface of a porous dielectric while depositing little or no silica on metal surfaces, comprising
a) an optional first step of cleaning the surfaces of the metal and the porous dielectric; and
b) exposing the surfaces to a protective material that reduces the reactivity of the metal surfaces to the reactions in part c);
c) exposing the surfaces to a metal or metalloid compound that generates acid sites on the outer surface and exposed outer pores of the porous dielectric;
d) exposing the surfaces to one or more silanol compound; and
e) optionally removing the protective material and any residual silica from the metal surfaces.

24. The method of claim 23, in which the cleaning step of part a) comprises oxidation followed by reduction or removal of the metal oxide.

25. The method of claim 23, in which the oxidation step comprises exposure to one or more members of the group comprising an oxygen-containing plasma, ultraviolet light and ozone.

26. The method of claim 24, in which the reduction or removal step comprises exposure to one or more members of the group comprising a hydrogen plasma, hydrogen, trixoane, alcohols, ketones, aldehydes, organic acids, beta-diketones, beta-ketimines, amidines and isonitriles.

27. The method of claim 23, in which the protective step of part b) comprises exposure to one or more members of the group comprising alkylthiols, dialkyldisulfides, alkylisonitriles, diazoalkanes and their fluorinated or partially fluorinated analogs that do not react with the surface of the porous dielectric.

28. The method of claim 23, in which the metal or metalloid compound of part c) comprises amides, amidinates, alkyls, alkoxides or halides.

29. The method of claim 23, in which the metal or metalloid of part c) comprises aluminum, boron, magnesium, scandium, lanthanum, yttrium, titanium, zirconium or hafnium.

30. The method of claim 23, in which the exposure to the metal or metalloid compound in part c) is sufficiently limited so that catalytic surfaces are not created on the surfaces of the pores in the interior of the dielectric.

31. The method of claim 23, in which the silanol in step d) is selected from the group comprising tris(tert-butoxy)silanol and tris(tert-penoxy)silanol.

32. The method of claim 23, in which the cleaning step of part e) comprises removal of residual silica by reactive ion etching, a fluorine-containing plasma or a vapor etch comprising hydrogen fluoride.

33. The method of claim 23, in which the protective layer is removed with a hydrogen plasma.
